(19) United States
(12) Patent Application Publication
(10) Pub. No.: US 2013/0114203 A1
(43) Pub. Date: May 9, 2013

(54) Systems, Apparatuses and Methods for Improving the Performance of Computing Devices

(71) Applicants: Sergey Ignatchenko, Innsbruck (AT); Dmytro Ivanchykhin, Kiev (UA)

(72) Inventors: Sergey Ignatchenko, Innsbruck (AT); Dmytro Ivanchykhin, Kiev (UA)

(21) Appl. No.: 13/290,253

(22) Filed: Nov. 7, 2011

(51) Int. Cl. H05K 7/00

(52) U.S. Cl. 361/679.41

(57) ABSTRACT

The present disclosure describes systems, methods, and apparatuses for increasing the performance of portable computing devices, such as smart phones, music players, and tablet computers, without risking damage to the device or its components that may result from excess heat generated by the increased performance. A portable computing device may be coupled to a larger device, such as a docking station, for the removal of excess heat. The portable computing device may confirm that it is docked, and request information regarding the docking station's ability to remove heat. The docking station may respond with characteristics, such as an indication that it possesses an operational heat sink. Based on the received information, the portable computing device may increase its performance, e.g. its processor speed, until the maximum safe operating temperature of the portable computing device has been reached.

### FIELD OF THE DISCLOSURE

The present invention relates to the field of improving the performance of portable computing devices, such as portable computers, smart phones, portable music players, personal digital assistants and the like. More specifically, the invention relates to the use of a larger device, such as a docking station, for the removal of heat from portable computing devices in order to improve their performance.

### BACKGROUND

Portable computing devices are ubiquitous today. Such devices may include, but are not limited to, portable computers (sometime referred to laptop computers), tablet computers, smart phones, personal digital assistants, music players and the like. Such portable computing devices typically include many different components that generate heat during their operation. The components may include, but are not necessarily limited to, one or more processors, memories, power supplies and/or other integrated circuits or circuit board components.

In particular, the components within portable computing devices often can operate at various clock speeds. By way of example and not limitation, the processor within a portable computing device typically has a maximum operating clock speed, but can also operate at lower clock speeds. The higher the clock speed at which the processor (or other components within the portable computing device, e.g., memory, video card, etc.) operates, the more heat that is generated within or by the portable computing device. If the heat is not adequately dissipated from the portable computing device, the portable computing device or components within it (e.g., the processor, memory, etc.) may be damaged.

Portable computing devices may also suffer from a disadvantage that because of limitations on their size and/or weight, they often cannot include adequate heat dissipation mechanisms. For this reason, the portable computing device may not possess sufficient heat dissipation capability to allow the device to operate at maximum capacity (e.g., for the processor to operate at maximum clock speed) when the device is operating in stand-alone mode (e.g., is not connected to a docking station or the like). For this reason, the portable computing device may not actually operate at its maximum operating capacity when it is in stand-alone mode.

Methods and apparatuses for providing additional heat dissipation capability to portable computing devices are known in the art. For example, it is known to connect a laptop computer or other portable computing device to a docking station whereby a passive (e.g., heat sink) or active (e.g., a fan) heat dissipation mechanism in the docking station helps to remove heat from the portable computing device. Systems also exist which permit users to dock small, portable devices, such as personal digital assistants, smart phones or music players, with another computing device such as a desktop or laptop computer.

Despite the additional heat dissipation capability that such external devices may provide to portable computing devices, improved methods, systems and techniques are needed by which portable computing devices may more effectively use the heat dissipation capabilities of docking apparatuses to maximize their performance without risking damage to the portable computing device or its component parts from excess heat.

### SUMMARY

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

The present disclosure describes systems, apparatuses and methods for increasing the performance of portable computing devices, without risking damage to the device or its components that may result from excess heat generated by the increased performance.

In one aspect of the present disclosure, a portable computing device may have a first interface for coupling the portable computing device to a docking apparatus with a second, complementary interface. The portable computing device and docking apparatus may have communication ports through which they establish one- or two-way communication between the portable computing device and the docking apparatus. The portable computing device may also have a battery capable of powering the device. The docking apparatus may include a heat dissipation mechanism that may assist the portable computing device to dissipate excess heat when the portable computing device and the docking apparatus are coupled to each other. The docking apparatus may further include a power supply suitable for providing extra power to the portable computing device, such as a secondary battery capable of recharging the device's battery.

Once the portable computing device and the docking apparatus are coupled, they may establish a communication link with each other whereby the portable computing device may request and/or the docking apparatus may provide information regarding at least one characteristic of the heat dissipation mechanism and/or at least one characteristic of the power supply. The portable computing device may increase the performance of at least one of its component parts (for example, but not limited to, increasing the clock speed at which a processor of the portable computing device operates). Thereafter, the portable computing device may determine the operating temperature of at least one of its component parts to ensure that the increased performance does not cause the operating temperature to exceed a predetermined maximum safe operating temperature. The portable computing device may continue to monitor the operating temperature of the at least one component part (either continuously or periodically) and continue to increase the performance of the at least one component part until the operating temperature exceeds the predetermined or pre-established maximum safe operating temperature.

For accomplishing the foregoing and related ends, certain illustrative aspects of the systems, apparatuses, and methods according to the present invention are described herein in connection with the following description and the accompanying figures. These aspects are indicative, however, of but a few of the various ways in which the principles of the invention may be employed and the present invention is intended to include all such aspects and their equivalents. Other advantages and novel features of the invention may become apparent from the following detailed description when considered in conjunction with the figures.

### BRIEF DESCRIPTION OF THE DRAWINGS

Non-limiting and non-exhaustive embodiments of the present invention are described with reference to the following figures.

FIG. 1 is an exemplary diagram of a portable computing device and a docking apparatus.

FIG. 2 is a block diagram illustrating an exemplary embodiment of a portable computing device and a docking apparatus.

FIGS. 3-6 are flow diagrams depicting the operation of various embodiments of the disclosure.

FIG. 7 is a diagram that clarifies why the present disclosure can be used to design portable computing devices with faster and/or more powerful processors or other components that can implement the systems, method and techniques disclosed herein.

### DETAILED DESCRIPTION

In the following detailed description, numerous specific details are set forth in order to provide a thorough understanding of the invention. In other instances, well known structures, interfaces, and processes have not been shown in detail in order not to unnecessarily obscure the invention. However, it will be apparent to one of ordinary skill in the art that those specific details disclosed herein need not be used to practice the invention and do not represent a limitation on the scope of the invention, except as recited in the claims. It is intended that no part of this specification be construed to effect a disavowal of any part of the full scope of the invention. Although certain embodiments of the present disclosure are described, these embodiments likewise are not intended to limit the full scope of the invention.

The present disclosure describes systems, apparatuses and methods for increasing the performance of portable computing devices. Such portable computing devices may include, but are not limited to, laptop computers, smart phones, personal digital assistants or music players. Those with ordinary skill in the art will recognize that the methods, systems and techniques of the present disclosure are applicable to any computing device that because of its size or weight, may not be able to contain sufficient heat dissipation mechanisms to allow the electronic components within the device (e.g., the processor, memory, etc.) to operate at maximum optimal speeds.

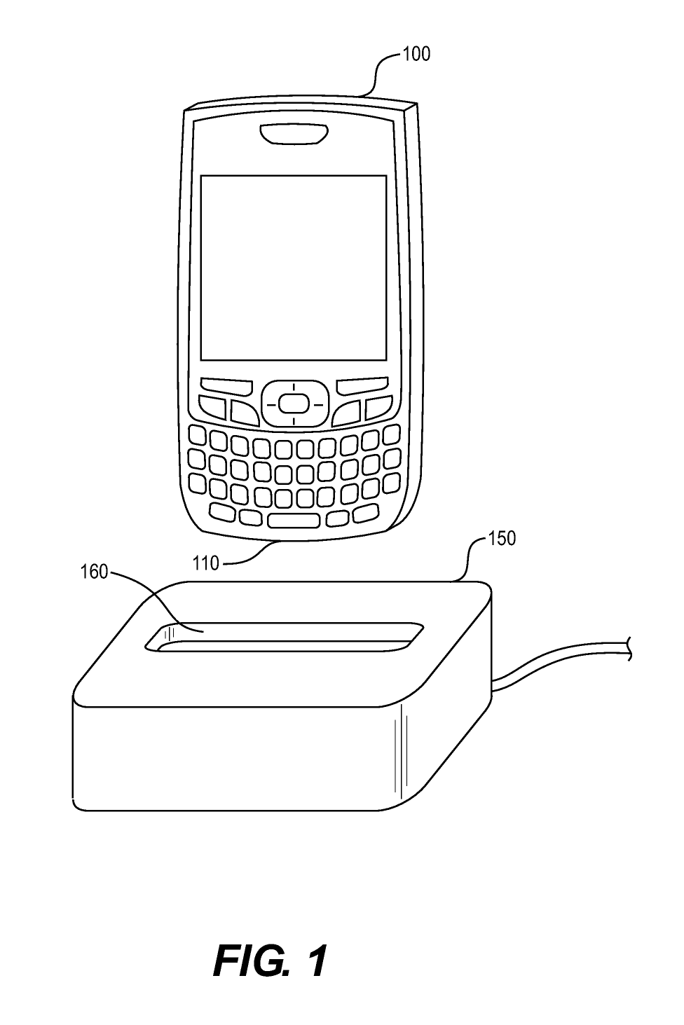

As shown in an exemplary fashion in FIG. 1, a portable computing device 100 may comprise an interface for coupling 110 to a docking apparatus 150. The portable computing device 100 may be any type of portable computing device, including, but not limited to, a laptop, a cell phone, a smart phone, a portable music player, a tablet computer, a portable gaming device, or the like.

The docking apparatus 150 has a corresponding interface 160 for physically coupling to the portable computing device 100. Many portable computing devices 100 are marketed and/or sold with corresponding docking apparatuses 150. The docking apparatus 150 may be, by way of non-limiting example, any form of dock, docking station, port replicator, breakout dock, converter dock, computer stand, mobile docking station, or other suitable apparatus for coupling to a portable computing device 100. The docking apparatus 150 may also be incorporated into another device. For example, the docking apparatus 150 may be incorporated into a laptop or desktop computer such that the portable computing device 100 can be docked or connected with the laptop or desktop computer through the docking apparatus.

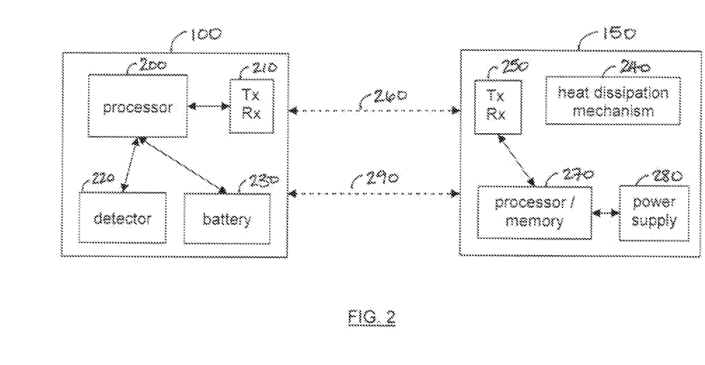

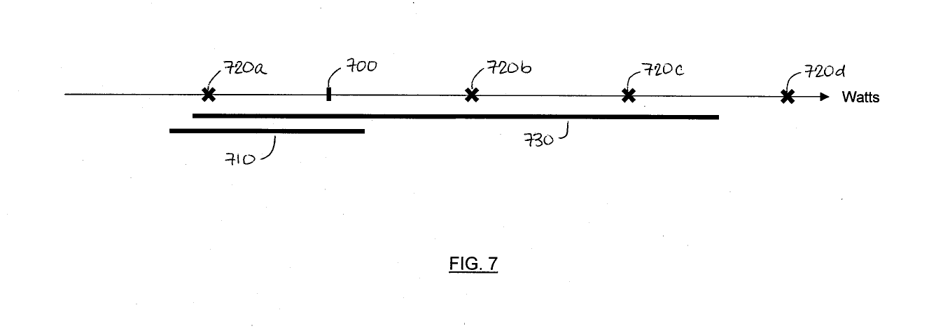

As shown in the exemplary block diagram of FIG. 2, the portable computing device 100 may comprise at least one processor 200. One having ordinary skill in the art will understand that this processor 200 may be any of a microcontroller, computer processor, programmable circuitry, application-specific integrated circuit (ASIC) or any other appropriate device. When selecting a processor 200, it may be desirable to consider its maximum operating speed and the amount of heat it will produce operating at this speed. This issue is discussed in more detail, below, with respect to FIG. 7. Although not shown on FIG. 2, one having ordinary skill in the art will understand that the portable computing device 100 may include one or more additional component parts, such as additional processors, memory, other data storage units, data transmission lines, communication ports and/or other specialized circuitry.

The portable computing device 100 may further comprise a communication port 210 which enables the portable computing device 100 to communicate with at least a docking apparatus 150, although this communication port 210 may also enable the portable computing device 100 to additionally communicate with other electronic devices. The communication port 210 may take any form of hardware or software, or combination thereof, appropriate for establishing and maintaining two-way communications, including, but not limited to, wired protocols such as serial, parallel, coaxial and USB, and wireless protocols such as Bluetooth, near field communications, infrared, IEEE 802.11, inductive data connectors and capacitive data connectors. One having ordinary skill in the art will understand, however, that these references are merely exemplary, and the invention is not limited to any specific form of communications technology.

The portable computing device 100 may additionally comprise a mechanism for determining the operating temperature of one or more component parts (hereinafter a “detector”) 220, such as the processor 200 and/or the communication port 210. As shown in FIG. 2, the detector 220 may, depending on the specific implementation, be a standalone component of the portable computing device 100. In an alternative embodiment, it might be combined with the processor 200 such as, by way of non-limiting example, in the form of an on-chip temperature sensor. In additional alternative embodiments, not pictured, the detector 220 may be a component of the docking apparatus 150, or separate from either device.

Additionally, the portable computing device 100 may comprise at least one battery or other suitable mechanism 230 for providing power to the processor 200, the communication port 210, the detector 220 and/or any other components of the portable computing device 100 which are not pictured.

The docking apparatus 150 may comprise at least one mechanism for removing heat 240 from a portable computing device 100 to which it is coupled. The mechanism for removing heat 240 may be any component, apparatus or mechanism suitable for removing heat from a small apparatus 100 such as, by way of example and not limitation, air cooling (such as by a traditional fan or a Sandia cooler), liquid submersion cooling, conductive cooling, spot cooling, passive or active heat-sink cooling, thermoelectric cooling, heat pipes and phase-change cooling.

Like the portable computing device 100, the docking apparatus 150 may further comprise a communication port 250, which may enable it to communicate with the communication port 210 of the portable computing device 100. This communication port 250 may similarly take any form of hardware or software, or combination thereof, as appropriate for establishing and maintaining a communications link 260 between the communication port 210 of the portable computing device 100 and the communication port 250 of the docking apparatus 150, including, but not limited to, wired protocols such as serial, parallel, coaxial and USB, and wireless protocols such as Bluetooth, near field communications, infrared, IEEE 802.11, inductive data connectors and capacitive data connectors. Again, one having ordinary skill in the art will understand that these references are merely exemplary, and the invention is not limited to these specific types of communications technology.

The docking apparatus 150 may further include one or more processors, memory, or other electronic components (collectively shown as processor 270) which enable it to retain information regarding its heat dissipation capabilities, to communicate those capabilities to the portable computing device 100 through the communication port 250, and otherwise interact with the portable computing device 100 in order to implement the methods and techniques discussed herein. If the docking apparatus 150 is incorporated into another device (e.g., a laptop or desktop computer), then the docking apparatus 150 may use the processing and communications capabilities of the other device instead of having its own.

Additionally, the docking apparatus 150 may further include a battery, charging circuit, or other suitable mechanism 280 for providing supplemental power to the portable computing device 100 and/or for charging the battery 230. In some embodiments, the power supply 280 may be a battery capable of directly powering the processor 200, communication port 210, or any other component of the portable computing device 100. If the docking apparatus is connected to an external power source (e.g., plugged into a power outlet), the power supply may alternatively or additionally be comprised of one or more circuits that transfer the power from the external source to the portable computing device. By way of example, and not limitation, if the docking apparatus is connected to a wall electrical outlet, it may include suitable circuitry for allowing the power from the electrical outlet to power the portable computing device and/or charge the portable computing device's battery 230. Conveyance of power from the docking apparatus 150 to the portable computing device 100 in this manner is illustrated via the optional power link shown as 290 on FIG. 2.

The portable computing device 100 may use this additional source of power to increase performance and/or power consumption of the processor 200. This may provide additional protection to the portable computing device 100 so as to prevent the battery 230 from overloading. One having ordinary skill in the art will understand that power may be provided by the docking apparatus 150 via the power link 290 to the portable computing device 100 in any suitable manner, including but not limited to wired connections or contactless mechanisms such as inductive coupling.

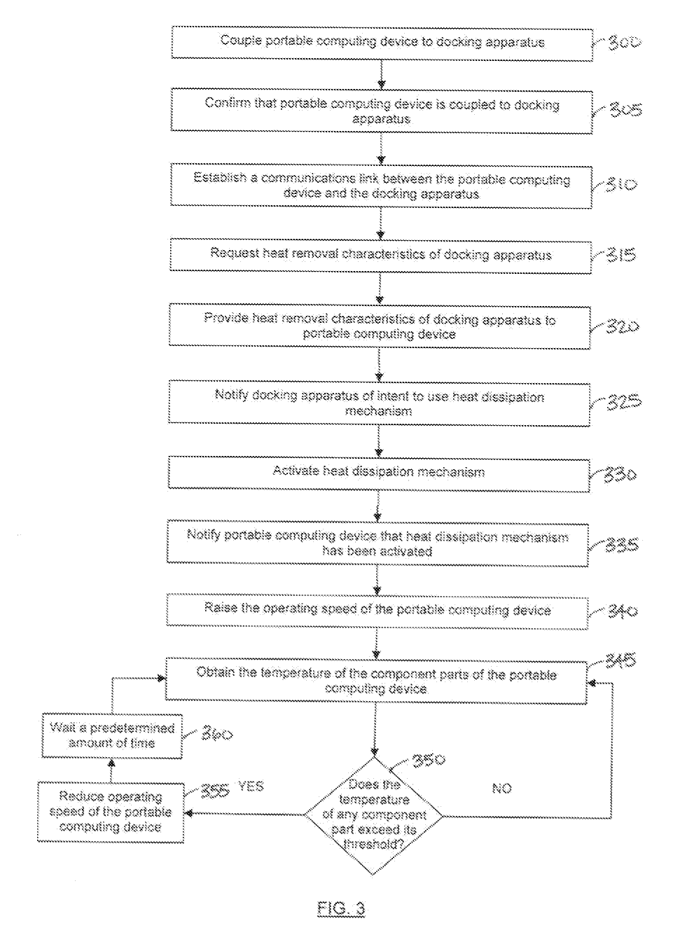

FIG. 3 is a flow diagram depicting one embodiment of a method for using the heat dissipation capabilities of the docking apparatus 150 to enable the portable computing device 100 to increase its computing performance (by, for example, operating at a higher clock speed) without risking damage to the portable computing device or its components as a result of excess heat generated through the increased performance.

At step 300, the portable computing device 100 may be coupled to the docking apparatus 150, and at step 305 the portable computing device 100 may confirm or receive an indication that it is coupled to a docking apparatus 150. By way of example and not limitation, upon the portable computing device 100 being coupled to the docking apparatus 150, the portable computing device 100 may receive a signal from the docking apparatus 150 confirming that the two devices are coupled. Alternatively, a physical component (not shown) on the docking apparatus 150 may trigger or depress a switch on the portable computing device 100 indicating that the two devices are coupled. As another alternative, the coupling of the two devices may close a circuit that indicates that the two devices are coupled. It is understood by those with ordinary skill in the art that there are many different techniques for providing an indication to the portable computing device 100 that it is coupled to a docking apparatus 150 and/or for providing an indication to the docking apparatus 150 that it is coupled to a portable computing device 100.

Depending on the nature of the heat dissipation mechanism 240, heat removal may begin as soon as the portable computing device 100 is coupled to the docking apparatus 150 and may continue coterminously with any additional steps. For example, a docking apparatus 150 equipped with a heat sink may begin removing heat generated by the portable computing device 100 as soon as it is coupled to the docking apparatus 150 at step 300, and may continue removing heat continuously until the portable computing device 100 is decoupled from the docking apparatus 150.

At step 310, the portable computing device 100 may establish a communication link 260 between itself and the docking apparatus 150. Alternatively, it may be the docking apparatus 150 that establishes the communication channel 260 with the portable computing device 100. One having ordinary skill in the art will understand that such a communications link 260 should be established in accordance with any protocol suitable for communications between the two communication ports 210, 250.

At step 315, the portable computing device 100 may initiate a request to the docking apparatus 150 seeking information from the docking apparatus 150 regarding at least one characteristic of its heat dissipation mechanism 240. The request may be initiated, for example, by software (not shown) executing on the processor 200 of the portable computing device 100. For example, the portable computing device 100 may seek confirmation that the docking apparatus 150 possesses a heat dissipation mechanism 240. In an alternate embodiment, the portable computing device 100 may seek confirmation that the heat dissipation mechanism 240 is available for use by the portable computing device 100. In still another embodiment, the portable computing device 100 may seek detailed information, such as an indicator that the heat dissipation mechanism 240 is “active” (such as a fan) versus “passive” (such as a conductive cooling system in which heat is distributed from the portable computing device 100 over the surface of the docking apparatus 150), or a status indicator based on a numerical range, in which, for example, 0 means no heat removal ability at all, and 5 means best heat removal characteristics. In yet another embodiment, the portable computing device 100 may seek the thermal design power of the docking apparatus 150, i.e., the maximum amount of power the docking apparatus 150 is physically capable of dissipating. One having ordinary skill in the art will understand that these descriptions are merely exemplary, however, and that the characteristics which may be sought may be proscribed by the specific implementation of the heat dissipation mechanism 240.

At step 320, the docking apparatus 150 may provide the requested information regarding the characteristics and capabilities of its heat dissipation mechanism 240 to the portable computing device 100. The information may be provided, for example, by software executing on the processor 270 of the docking apparatus 150 and may be received by the processor 200 of the portable computing device 100. In an alternative embodiment, the docking apparatus 150 may automatically provide this information to the portable computing device 100 upon establishment of a communication link 260 between the docking apparatus 150 and the portable computing device 100 without waiting for a request from the portable computing device 100.

When the portable computing device 100 receives information about the docking apparatus' heat dissipation mechanism 240, at step 325, if appropriate in the specific context, the portable computing device 100 may provide an indication to the docking apparatus 150 that the portable computing device 100 intends to use the docking apparatus' heat dissipation mechanism 240, and at step 330 the docking apparatus 150 may initiate the use of the heat dissipation mechanism 240. For example, if the heat dissipation mechanism 240 is a fan (or includes a fan), or the heat dissipation mechanism 240 otherwise includes components that are capable of activation or de-activation, then at step 330 the docking apparatus 150 may activate the fan (or other heat dissipation mechanism 240). At step 335 the docking apparatus 150 may provide an indication to the portable computing device 100 that the heat dissipation mechanism 240 has been activated.

In other embodiments in which the heat dissipation mechanism 240 does not need to be activated in order to operate (e.g., the heat dissipation mechanism 240 is a passive heat sink) steps 325, 330 and 335 may not be necessary. Instead, the docking apparatus 150 may begin to dissipate heat from the portable computing device 100 upon coupling of the two devices together.

At step 340, after the portable computing device 100 has determined that the docking apparatus' heat dissipation mechanism 240 is available for its use, the portable computing device 100 may increase its operating capabilities. By way of example and not limitation, the portable computing device 100 may increase the clock speed or frequency at which its processor 200 operates, increase the clock speed or frequency at which one or more other components operate, or increase the clock speed or frequency of its processor 200 and one or more components. The increase in clock speed or frequency could be in the form of any predetermined or dynamically-generated value. In one embodiment, at step 340 the portable computing device 100 may increase the operating speed of its processor 200 and/or one or more of its components to their maximum rated clock speeds or frequencies. One having ordinary skill in the art will understand that the precise nature of how and in what increment to increase performance may be based on the specific characteristics of the portable computing device 100.

At step 345, the detector 220 may be used to obtain the current operating temperature of one or more of the component parts of the portable computing device 100. It may be desirable, in certain embodiments, to wait for a predetermined amount of time to lapse between raising the operating speed at step 340 and obtaining the current operating temperature at step 345. For example, it may take a finite period of time for the temperature of certain component parts to increase as a result of increased operating speed. Therefore, it may not be possible to obtain an accurate temperature reading if step 345 is performed immediately after the operating speed has been raised.

If, as determined at step 350, the operating temperature of the portable computing device 100 or its component parts does not exceed maximum safe operating temperatures then there is no need to reduce the performance of the portable computing device 100 (e.g., reduce the clock speed at which the processor 200 operates) at step 355. Nevertheless, as shown in FIG. 3, the method may continuously or periodically return to step 345 so that the detector 220 may monitor the operating temperature of the portable computing device 100 to determine whether the device 100 or its component parts continue to operate within an allowable temperature range.

If at any time at step 350 the operating temperature of the portable computing device 100 or its component parts exceeds a predetermined safe operating temperature, then at step 355 the portable computing device 100 may reduce its operating speed (or the operating speed of one or more of its component parts) by a predetermined amount. This predetermined amount may be previously set amount or an amount that is dynamically generated based on one or more operating characteristics of the portable computing device 100 and/or the docking apparatus 150.

After reducing the operating speed at step 355, the portable computing device 100 may wait for a predetermined amount of time at step 360 before returning to step 345 to determine the operating temperature of the portable computing device 100 or one or more of its relevant components. The reason for the wait at step 360 is to allow a sufficient period of time to pass to enable the temperature of the portable computing device 100 and/or its component parts to stabilize at the decreased performance level before obtaining the operating temperature. If one does not wait for the temperature to stabilize at the lower performance level, then it may be possible that the performance will be decreased too much before the temperature is reduced below the maximum operating temperature, i.e., overshoot the amount of decrease that is necessary to lower the operating temperature below the maximum safe level.

Once the method has waited for the predetermined amount of time at step 360, it may return to step 345 to check its operating temperature to ensure that it is now operating in a safe temperature range and repeat steps 345, 350, 355 and 360 as necessary until it reaches a safe operating temperature.

There may be events that interrupt the method disclosed in FIG. 3 and cause the portable computing device 100 to return to its original operating speed, i.e. the speed at which it was operating before it was raised pursuant to step 340. For example, if the portable computing device 100 is physically decoupled from the docking apparatus 150, the portable computing device 100 may return to operating at the speed at which it was operating before beginning the method of FIG. 3. Accordingly, the portable computing device 100 may periodically or continuously monitor whether it remains coupled to the docking apparatus 150. In an alternative example, if the communications link 260 between the portable computing device 100 and the docking apparatus 150 is interrupted for some predetermined amount of time, the portable computing device 100 may reduce its operating speed. One having ordinary skill in the art will understand that the foregoing examples are merely exemplary, and the portable computing device 100 may be configured to respond to decoupling, errors or other events by interrupting the method of FIG. 3 and reducing its operating speed.

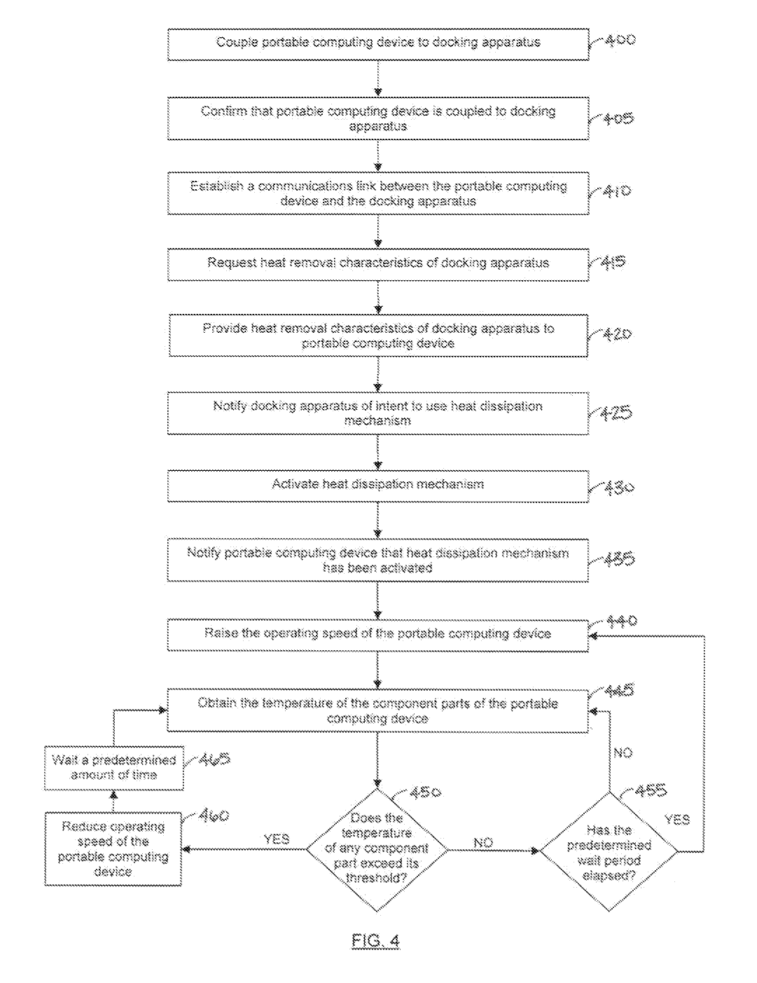

FIG. 4 is a flow diagram depicting a different embodiment of a method for using the heat dissipation capabilities of the docking apparatus 150 to enable the portable computing device 100 to increase its computing performance (by, for example, operating at a higher clock speed) without risking damage to the portable computing device 100 or its components as a result of excess heat generated through the increased performance. Some of the steps depicted in the embodiment of FIG. 4 are similar to those in the embodiment of FIG. 3. For the sake of brevity, some of the alternatives, options and the detailed explanations discussed with respect to FIG. 3 are not repeated during the discussion of the embodiment of FIG. 4, but it is to be understood that those alternatives, options and detailed discussions are equally applicable to the embodiment of FIG. 4.

At step 400, the portable computing device 100 may be coupled to the docking apparatus 150, and at step 405 the portable computing device 100 may confirm or receive an indication that it is coupled to a docking apparatus 150. At step 410, the devices may establish a communication channel 260 between themselves. At step 415, the portable computing device 100 may initiate a request to the docking apparatus 150 seeking information from the docking apparatus 150 regarding at least one characteristic of its heat dissipation mechanism 240. At step 420, the docking apparatus 150 may provide the requested information regarding the characteristics and capabilities of its heat dissipation mechanism 240 to the portable computing device 100.

At step 425, if appropriate in the specific context, the portable computing device 100 may provide an indication to the docking apparatus 150 that the portable computing device 100 intends to use the docking apparatus' heat dissipation mechanism 240, and at step 430 the docking apparatus 150 may initiate the use of the heat dissipation mechanism 240. For example, if the heat dissipation mechanism 240 is a fan (or includes a fan), or the heat dissipation mechanism 240 otherwise includes components that are capable of activation or de-activation, then at step 430 the docking apparatus 150 may activate the fan (or other heat dissipation mechanism). At step 435 the docking apparatus 150 may provide an indication to the portable computing device 100 that the heat dissipation mechanism 240 has been activated. In other embodiments, in which the heat dissipation mechanism does not need to be activated in order to operate (e.g., a passive heat sink), steps 425, 430 and 435 may not be necessary. Instead, by way of non-limiting example, the docking apparatus 150 may begin to dissipate heat from the portable computing device 100 upon coupling of the two devices together.

At step 440, the portable computing device 100 may increase its performance by, for example, increasing the clock speed of the processor 200 or by increasing the clock speed or other operating characteristic of one or more components of the portable computing device 100. In one embodiment, the decision to increase the performance of the portable computing device 100, as well as how much to increase the performance, may be made as a function of the information received from the docking apparatus 150 at step 420. In one embodiment according to the method of FIG. 4, the performance of the portable computing device 100 may increase by a predetermined or dynamically generated amount that is less than the maximum performance (e.g., maximum process clock speed) at which the portable computing device 100 is capable of operating.

At step 445, the portable computing device 100 may use the detector 220 to determine its operating temperature or the operating temperature of one or more of its components. As discussed in greater detail with respect to FIG. 3, it may be desirable, in certain embodiments, to wait for a predetermined amount of time to lapse between performing the steps of increasing the performance at 440 and obtaining the operating temperature at step 445.

If, at step 450, the relevant operating temperature obtained at step 445 is less than a maximum operating temperature, then the portable computing device may be able to continue to increase its performance without exceeding a maximum safe operating temperature. To ensure that the performance is not increased too fast, however—i.e., to ensure that the operating temperature has stabilized at the current performance level and is not continuing to increase before increasing the performance again—at step 455 the method may determine whether a predetermined amount of time has passed since the previous performance increase. The predetermined amount of time generally is an amount of time by which one would expect the operating temperature of the portable computing device 100 or its component parts to have stabilized and no longer be increasing since the last performance increase, and will depend on the specific operating characteristics of the portable computing device 100 and/or its component parts.

If the predetermined amount of time has not elapsed at step 455, then the method may return to step 445 and continue to obtain the operating temperature of the portable computing device and/or its component parts. If at step 455, the predetermined amount of time has elapsed, then the method will return to step 440 and increase the performance of the portable computing device 100 and/or its component parts by an additional incremental step, which may be a predetermined or dynamically generated amount of increase in performance. Assuming that the operating temperature of the portable computing device 100 (or the operating temperature of one or more of its relevant components) does not exceed the maximum operating temperature, then steps 440, 445, 450 and 455 may be repeated until the portable computing device 100 reaches its maximum operating capability (e.g., the processor 200 is operating at maximum frequency).

If at step 450, the operating temperature of the portable computing device 100 (or one or more of its relevant components) is at or above a predetermined maximum safe operating temperature, then at step 460 the portable computing device 100 may decrease its performance (or the performance of one or more of its components) by a predetermined amount in order for the device 100 not to generate as much heat. This predetermined amount may be previously set amount or an amount that is dynamically generated based on one or more operating characteristics of the portable computing device 100 and/or the docking apparatus 150. Thereafter, for the reasons discussed with respect to FIG. 3, the method may then wait for a predetermined amount of time at step 465 before returning to step 445 to so as to enable the temperature of the portable computing device 100 and/or its component parts to stabilize at the decreased performance level.

Also similar to the more detailed discussion with respect to FIG. 3, one having ordinary skill in the art will understand that the portable computing device 100 may be configured to respond to decoupling, errors or other events by interrupting the method of FIG. 4 and reducing its operating speed.

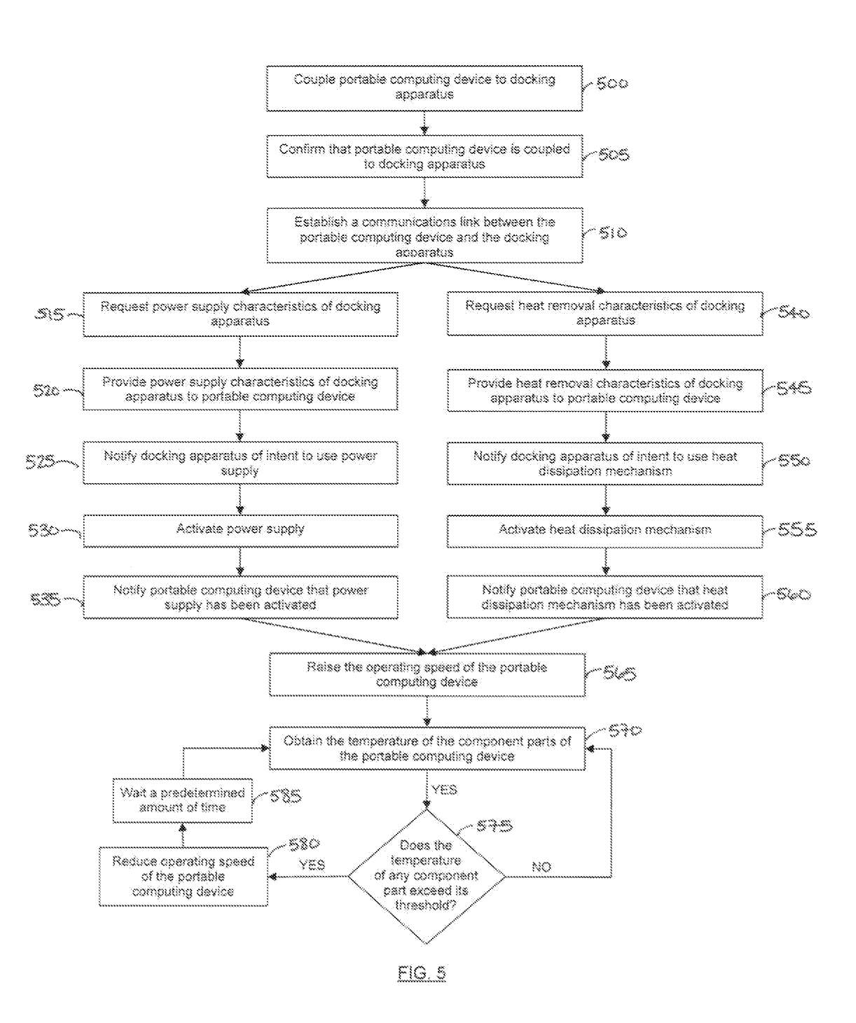

FIG. 5 is a flow diagram showing another embodiment of a method for increasing the performance of the portable computing device 100. Some of the steps depicted in the embodiment of FIG. 5 are similar to those in the embodiments of FIGS. 3 and 4. For the sake of brevity, some of the alternatives, options and the detailed explanations discussed with respect to FIGS. 3 and 4 are not repeated during the discussion of the embodiment of FIG. 5, but it is to be understood that those alternatives, options and detailed discussions are equally applicable to the embodiment of FIG. 5.

At step 500, the portable computing device 100 may be coupled to the docking apparatus 150, and at step 505 the portable computing device 100 may confirm or receive an indication that it is coupled to a docking apparatus 150. At step 510, the devices may establish a communication channel 260 between themselves.

At step 515, the portable computing device 100 may initiate a request to the docking apparatus 150 seeking information from the docking apparatus 150 regarding at least one characteristic of the power supply 280. At step 520, the docking apparatus 150 may provide the requested information regarding the characteristics and capabilities of power supply 280 to the portable computing device 100. The characteristics of the power supply about which information may be requested or provided may include, but are not necessarily limited to, the amount of Watts that is available to the portable computing device 100, whether the power supply 280 is a battery or another external source (e.g., power from a wall electric outlet), or the like. At step 525 the portable computing device 100 may provide an indication to the docking apparatus 150 that the portable computing device 100 intends to use the docking apparatus' power supply 280. At step 530 the docking apparatus 150 may initiate use of the power supply 280. For example, if the power supply 280 includes components that are capable of activation or de-activation (such as, for example, a charging circuit which is ordinarily deactivated), then at step 530 the docking apparatus 150 may activate those components. At step 535 the docking apparatus 150 may provide an indication to the portable computing device 100 that the power supply 280 has been activated. In other embodiments, in which the power supply 280 does not need to be activated in order to operate (e.g., a passive battery), steps 525, 530 and 535 may not be necessary.

At step 540, the portable computing device 100 may initiate a request to the docking apparatus 150 seeking information from the docking apparatus 150 regarding at least one characteristic of its heat dissipation mechanism 240. At step 545, the docking apparatus 150 may provide the requested information regarding the characteristics and capabilities of its heat dissipation mechanism 240 to the portable computing device 100. At step 550 the portable computing device 100 may provide an indication to the docking apparatus 150 that the portable computing device 100 intends to use the docking apparatus' heat dissipation mechanism 240, and at step 555 the docking apparatus 150 may initiate the use of the heat dissipation mechanism 240. At step 560 the docking apparatus 150 may provide an indication to the portable computing device 100 that the heat dissipation mechanism 240 has been activated.

At step 565, the portable computing device 100 may increase its operating capabilities. In one embodiment, as pictured in FIG. 5, at step 565 the portable computing device 100 may increase the operating speed of its processor 200 and/or one or more of its components to their maximum rated clock speeds or frequencies. One having ordinary skill in the art will understand that the precise nature of how and in what increment to increase performance may be based on the specific characteristics of the portable computing device 100.

At step 570, the detector 220 may be used to obtain the current operating temperature of one or more of the component parts of the portable computing device 100. As discussed in greater detail with respect to FIG. 3, it may be desirable, in certain embodiments, to wait for a predetermined amount of time to lapse before obtaining the operating temperature at step 570.

If, as determined at step 575, the operating temperature of the portable computing device 100 or its component parts does not exceed maximum safe operating temperatures then there is no need to reduce the performance of the portable computing device 100 at step 580. Nevertheless, as shown in FIG. 5, the method may continuously or periodically return to step 570 so that the detector 220 may monitor the operating temperature of the portable computing device 100 to determine whether the device 100 or its component parts continue to operate within an allowable temperature range.

If at any time at step 575 the operating temperature of the portable computing device 100 or its component parts exceeds a predetermined safe operating temperature, then at step 580 the portable computing device 100 may reduce its operating speed (or the operating speed of one or more of its component parts) by a predetermined amount. Thereafter, for the reasons discussed with respect to FIGS. 3 and 4, the method may then wait for a predetermined amount of time at step 585 before returning to step 570 to so as to enable the temperature of the portable computing device 100 and/or its component parts to stabilize at the decreased performance level.

In certain embodiments, it may be desirable to perform the steps of using the power supply 280 and the steps of using the heat dissipation mechanism 240 concurrently. By way of non-limiting example, as shown in FIG. 5, steps 515 through 535 may be performed in parallel with steps 540 through 560. In alternate embodiments, it may be desirable to perform all steps sequentially. One having ordinary skill in the art will understand that these steps may be performed in any manner suitable for accomplishing the objectives described herein.

Similar to the more detailed discussion with respect to FIG. 3, one having ordinary skill in the art will understand that the portable computing device 100 may be configured to respond to decoupling, errors or other events by interrupting the method of FIG. 5 and reducing its operating speed.

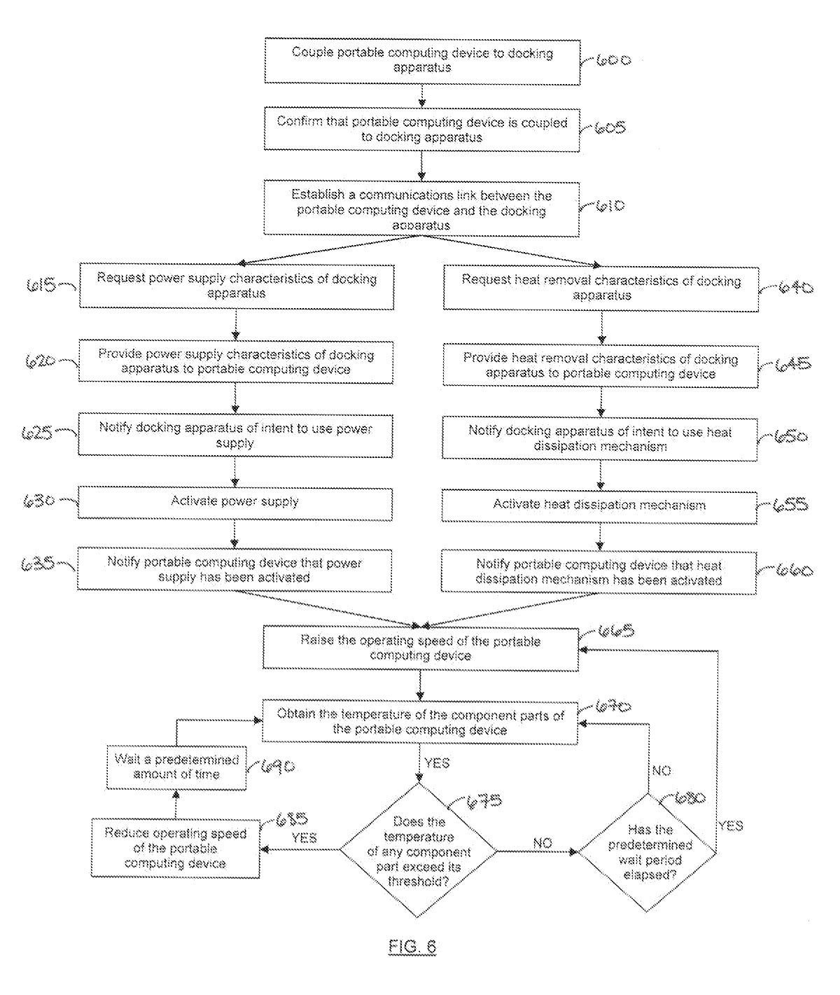

FIG. 6 is a flow diagram depicting yet another embodiment of a method for increasing the performance of the portable computing device 100. Some of the steps depicted in the embodiment of FIG. 6 are similar to those in the embodiments of FIGS. 3, 4 and 5. For the sake of brevity, some of the alternatives, options and the detailed explanations discussed with respect to those foregoing figures are not repeated during the discussion of the embodiment of FIG. 6, but it is to be understood that those alternatives, options and detailed discussions are equally applicable to the embodiment of FIG. 6.

At step 600, the portable computing device 100 may be coupled to the docking apparatus 150, and at step 605 the portable computing device 100 may confirm or receive an indication that it is coupled to a docking apparatus 150. At step 610, the devices may establish a communication channel 260 between themselves. At step 615, the portable computing device 100 may initiate a request to the docking apparatus 150 seeking information from the docking apparatus 150 regarding at least one characteristic of the power supply 280.

At step 620, the docking apparatus 150 may provide the requested information regarding the characteristics and capabilities of power supply 280 to the portable computing device 100. At step 625 the portable computing device 100 may provide an indication to the docking apparatus 150 that the portable computing device 100 intends to use the docking apparatus' power supply 280, and at step 630 the docking apparatus 150 may initiate the use of the power supply 280. In other embodiments, in which the power supply 280 does not need to be activated in order to operate, steps 625, 630 and 635 may not be necessary.

At step 640, the portable computing device 100 may initiate a request to the docking apparatus 150 seeking information from the docking apparatus 150 regarding at least one characteristic of its heat dissipation mechanism 240. At step 645, the docking apparatus 150 may provide the requested information regarding the characteristics and capabilities of its heat dissipation mechanism 240 to the portable computing device 100. At step 650 the portable computing device 100 may provide an indication to the docking apparatus 150 that the portable computing device 100 intends to use the docking apparatus' heat dissipation mechanism 240, and at step 655 the docking apparatus 150 may initiate the use of the heat dissipation mechanism 240. At step 660 the docking apparatus 150 may provide an indication to the portable computing device 100 that the heat dissipation mechanism 240 has been activated. In other embodiments, in which the heat dissipation mechanism 240 does not need to be activated in order to operate, steps 650, 655 and 660 may not be necessary.

At step 665, the portable computing device 100 may increase its performance. In one embodiment, the decision to increase the performance of the portable computing device 100, as well as how much to increase the performance, may be made as a function of the information received from the docking apparatus 150 at steps 620 and/or 645. In one embodiment according to the method of FIG. 6, the performance of the portable computing device 100 may increase by a predetermined or dynamically generated amount that is less than the maximum performance (e.g., maximum process clock speed) at which the portable computing device 100 is capable of operating.

At step 670, the portable computing device 100 may determine its operating temperature or the operating temperature of one or more of its components. As discussed in greater detail with respect to FIG. 3, it may be desirable, in certain embodiments, to wait for a predetermined amount of time to lapse between raising the performance at step 665 and obtaining the operating temperature at step 670.

If, at step 675, the relevant operating temperature obtained at step 670 is less than a maximum operating temperature, then, as discussed in greater detail with respect to FIG. 4, the portable computing device 100 may perform the subsequent step 680 of determining whether a predetermined waiting period has elapsed. If the time period has not lapsed, the device 100 may return to the step 670 of obtaining the temperature of its component parts. If the time period has lapsed, the device 100 may repeat step 665 and increase its performance by an additional incremental step, which may be a predetermined or dynamically generated amount of increase in performance. Assuming that the operating temperature of the portable computing device 100 (or the operating temperature of one or more of its relevant components) does not exceed the maximum operating temperature, then steps 665, 670, 675 and 680 may be repeated until the portable computing device 100 reaches its maximum operating capability (e.g., the processor 200 is operating at maximum frequency).

If at step 675, the operating temperature of the portable computing device 100 (or one or more of its relevant components) is at or above a predetermined maximum safe operating temperature, then at step 685 the portable computing device 100 may decrease its performance (or the performance of one or more of its components) by a predetermined amount in order for the device 100 not to generate as much heat. Thereafter, for the reasons discussed with respect to FIGS. 3-5, the method may wait a predetermined amount of time at step 690 before returning to step 670 to determine the operating temperature of the portable computing device 100 or one or more of its relevant components.

In certain embodiments, it may be desirable to perform the steps of using the power supply 280 and the steps of using the heat dissipation mechanism 240 concurrently. By way of non-limiting example, as shown in FIG. 6, steps 615 through 635 may be performed in parallel with steps 640 through 660. In alternate embodiments, it may be desirable to perform all steps sequentially. One having ordinary skill in the art will understand that these steps may be performed in any manner suitable for accomplishing the objectives described herein.

Similar to the more detailed discussion with respect to FIG. 3, one having ordinary skill in the art will understand that the portable computing device 100 may be configured to respond to decoupling, errors or other events by interrupting the method of FIG. 6 and reducing its operating speed.

The foregoing disclosure has described apparatuses, methods and systems for removing heat from a portable computing device 100 through the use of a docking apparatus 150. These disclosures may enable designers of portable computing devices 100 to incorporate faster and/or more powerful components into their devices, including but not limited to the processor 200.

It is understood that a portable computing device 100 may have a thermal design power (TDP, sometimes also referred to as thermal design point) of x Watts. TDP is a well-understood concept to those with ordinary skill in the art, and generally speaking, is a representation of the maximum amount of power that a device is required to and/or is capable of dissipating. The thermal design power of the portable computing device 100 is represented on FIG. 7 as the reference point 700. FIG. 7 is intended to relatively depict the several different thermal design powers discussed herein and it is to be understood that FIG. 7 is not to scale.

If the portable device 100 has a thermal design power 700, absent the systems and methods of the current disclosure, the designer of such a portable device 100 may select a processor 200 (and/or other heat generating components) having a range of power dissipation 710 around the TDP value 700 and which, at its maximum, is not substantially greater than the TDP value 700. This allows the processor 200 to generally operate at its optimal capability when the portable computing device 100 is used in a stand-alone manner while eliminating any waste of resources through use of faster or more powerful processors (i.e., if the heat dissipation of the processor 200 greatly exceeds the thermal design power of the portable computing device 100, the processor cannot be run at maximum capacity and its excess computational power is wasted).

As discussed herein, however, the portable computing device 100 can be designed to be coupled to one or more docking apparatuses 150. By way of example and not limitation, a smart phone might be designed to dock with a small set of speakers, an alarm clock, and a laptop, each of which may be equipped with different heat dissipation mechanisms 240 or no heat dissipation mechanism 240. Each docking apparatus 150 with which the portable computing device 100 may be coupled may have different heat dissipation capabilities such that each combination of the portable computing device 100 and a different docking apparatus 150 may have a different combined thermal design power. These different combinations of thermal design power are represented as points 720a, 720b, 720c and 720d on FIG. 7. It is to be understood that these points are representative, that there may be any number of different combined thermal design points depending on the number of docking apparatuses with which the portable computing device 100 may be coupled, and that the number of representative combined thermal design powers shown in FIG. 7 is not intended to be limiting in any manner.

As is also shown in FIG. 7, although many combinations of the portable computing device 100 and a docking apparatus 150 may have a combined thermal design power that is greater than the thermal design point 700 of the portable computing device 100 (as depicted by TDPs 720b, 720c and 720d, for example), the present disclosure does not intend to suggest that each combination of the portable computing device 100 and a docking apparatus 150 necessarily has a combined TDP that is greater than the TDP of the portable computing device 100 operating in stand-alone mode. Such a possibility of a lower combined TDP is shown as point 710a in FIG. 7.

Use of the systems, apparatuses and methods as described herein may permit designers of portable computing devices 100 to select more powerful processors 200 (and/or other heat generating components) without wasting their excess capacity. A designer of portable computing devices 100, being aware of the combined thermal design powers of the portable computing device and the various docking apparatuses with which the portable computing device may be coupled (representatively shown as 720a through 720d) may use this information to select more powerful and/or faster components for the device 100. For example, if a portable computing device 100 is expected to be coupled to one or more different docking apparatuses 150 for at least some amount of time, a processor 200 (and/or other heat generating components) can be chosen to have power dissipation in a range depicted as 730 in FIG. 7. As shown on FIG. 7, this range 730 may include values of TDP that can be achieved only when the portable computing device 100 is coupled to some (but not necessarily all) docking apparatuses 150, and may have an upper bound that is greater than the range 710.

When the components of a portable computing device 100 (including the processor 200) are selected in the manner discussed herein, the processor 200 (and/or other heat generating components) may operate at less than its maximum operating speed during times when the portable computing device 100 is used alone (or when the combined thermal design power of the portable device 100 and docking apparatus 150 is less than the TDP of the portable device 100 alone), and the processor 200 may operate at higher speeds when the portable computing device 100 is coupled to a docking apparatus 150 with a combined thermal design power that is greater than the TDP of the portable computing device 100 alone. The increase in operating speed and/or performance upon coupling to a docking apparatus 150 with an improved combined TDP may be accomplished according to the systems, methods and techniques described herein.

In the embodiments disclosed herein, certain steps are described as being performed by the portable computing device 100 and certain other steps are described as being performed by the docking apparatus 150. It is to be understood that these descriptions are merely exemplary and are not intended to limit the scope of the disclosure in any way. Those with ordinary skill in the art will recognize that the performance of the steps described herein may be divided between the portable computing device 100, the docking apparatus 150, or even another apparatus or mechanism without deviating from the disclosure. By way of example, and not by limitation, the discussion with respect to FIGS. 3 through 6 states that the portable computing device 100 determines its operating temperature. But it could just as well be that the docking apparatus 150 (or another device or mechanism) determines the operating temperature of the portable computing device 100 or one or more of its components. Similarly, it is within the scope of the present disclosure that other steps or functionalities described are performed by a device or mechanism other than the one specifically provided as an example.

While specific embodiments and applications of the present invention have been illustrated and described, it is to be understood that the invention is not limited to the precise configuration and components disclosed herein. The terms, descriptions and figures used herein are set forth by way of illustration only and are not meant as limitations. Various modifications, changes, and variations which will be apparent to those skilled in the art may be made in the arrangement, operation, and details of the apparatuses, methods and systems of the present invention disclosed herein without departing from the spirit and scope of the invention. By way of non-limiting example, those with ordinary skill in the art recognize that certain steps and functionalities described herein may be omitted without detracting from the scope or performance of the embodiments described herein.

The various illustrative logical blocks, modules, circuits, and algorithm steps described in connection with the embodiments disclosed herein may be implemented as electronic hardware, computer software, or combinations of both. To illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. The described functionality can be implemented in varying ways for each particular application, but such implementation decisions should not be interpreted as causing a departure from the scope of the present invention.

The steps of a method or algorithm described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art.

The methods disclosed herein comprise one or more steps or actions for achieving the described method. The method steps and/or actions may be interchanged with one another without departing from the scope of the present invention. In other words, unless a specific order of steps or actions is required for proper operation of the embodiment, the order and/or use of specific steps and/or actions may be modified without departing from the scope of the present invention.

What is claimed is:

1. A system for increasing the performance of a portable computing device comprising: a portable computing device including at least one component part capable of operating at different clock speeds, a docking apparatus, a communication channel between the portable computing device and the docking apparatus, and at least one heat dissipation mechanism on the docking apparatus for dissipating heat from the portable computing device, wherein the docking apparatus is configured to communicate at least one characteristic of the heat dissipation mechanism to the portable computing device over the communication channel.

2. The system of claim 1 further comprising a detector to detect the operating temperature of the at least one component part, wherein the portable computing device is configured to increase the performance of the at least one component part and thereafter determine whether the operating temperature of the at least one component part exceeds a predetermined amount.

3. The system of claim 2, wherein the portable computing device is configured to increase the performance of the at least one component part by increasing a clock speed at which the component part operates.

4. The system of claim 1 wherein the docking apparatus further comprises a power supply and wherein the docking apparatus is configured to communicate at least one characteristic of the power supply to the portable computing device over the communication channel.

5. A method for increasing the performance of a portable computing device, the portable computing device comprising a first interface for coupling to a docking apparatus and a first communication port for communication between the portable computing device and the docking apparatus, the method comprising the steps of:
coupling the portable computing device to the docking apparatus, the docking apparatus having a second interface for coupling to the portable computing device, a heat dissipation mechanism and a second communication port;
establishing a communication link between the portable computing device and the docking apparatus through the first and second communication ports;
increasing the performance of the portable computing device; and
determining the operating temperature of at least one component part of the portable computing device.

6. The method of claim 5 further comprising the step of requesting information regarding at least one characteristic of the heat dissipation mechanism.

7. The method of claim 6, wherein the heat dissipation mechanism is one that can be activated or deactivated, the method further comprising requesting that the heat dissipation mechanism be activated.

8. The method of claim 5 further comprising the step of reducing the performance of the portable computing device if the operating temperature of the at least one component part exceeds a predetermined amount.

9. The method of claim 5 wherein increasing the performance of the portable computing device comprises increasing a clock speed at which the at least one component part of the portable computing device operates.

10. The method of claim 5 further comprising repeating the increasing and determining steps iteratively until the operating temperature of the at least one component part reaches or exceeds a predetermined amount.

11. The method of claim 5, wherein the docking apparatus further comprises a power supply, and the method further comprises requesting information regarding at least one characteristic of the power supply.

12. A portable computing device capable of increasing its performance when coupled to a docking apparatus with a heat dissipation mechanism comprising: an interface capable of coupling the portable computing device to the docking apparatus, at least one component part capable of operating at different clock speeds, a detector capable of detecting an operating temperature of the at least one component part, a communication port capable of establishing a communication link with the docking apparatus, and a processor for receiving at least one characteristic of the heat dissipation mechanism of the docking apparatus, wherein the portable computing device is configured to increase the performance of the at least one component part when the portable computing device is coupled to the docking apparatus and thereafter detect the operating temperature of the at least one component part.

13. The device of claim 12 wherein the docking apparatus to which the device is coupled further comprises a power supply and wherein the processor is further configured to receive at least one characteristic of the power supply of the docking apparatus.

14. The portable computing device of claim 12, wherein the portable computing device is configured to increase the performance of the at least one component part by increasing a clock speed at which the component part operates.

15. A docking apparatus comprising: an interface capable of coupling the docking apparatus to a portable computing device, a communication port capable of communicating over a communication link to the computing device, a heat dissipation mechanism having at least one characteristic, and a processor for communicating the at least one characteristic of the heat dissipation mechanism to the portable computing device through the communication port.

16. The docking apparatus of claim 15 wherein the heat dissipation mechanism is capable of being activated or deactivated.

17. The apparatus of claim 15 further comprising a power supply having at least one characteristic, wherein the processor is configured to communicate the at least one characteristic of the power supply to the portable computing device through the communication port.
